(19) United States
(12) Patent Application Publication
(10) Pub. No.: US 2005/0068829 A1
(43) Pub. Date: Mar. 31, 2005

(54) Refresh rate adjustment

(75) Inventor: Jong-Hoon Oh, Chapel Hill, NC (US)

Correspondence Address: Dicke, Billig & Czaja, PLLC, Fifth Street Towers, Suite 2250, 100 South Fifth Street, Minneapolis, MN, 55402, US

(73) Assignee: Infineon Technologies North America Corp.

(21) Appl. No.: 10/672,243

(22) Filed: Sep. 25, 2003

(51) Int. Cl. G11C 7/00

(52) U.S. Cl. 365/222

(57) ABSTRACT

The present invention is a random access memory device assembled into a chip package with a refresh request control circuit, and a method for using the same. The refresh request control circuit includes a first circuit configured to receive a first refresh rate signal with a first refresh rate signal frequency. The first circuit produces a second refresh rate signal with a second refresh rate signal frequency. The refresh request control circuit also includes a second circuit configured to receive the first refresh rate signal and the second refresh rate signal. The refresh request control circuit also includes a final fusing element coupled to the second circuit. The final fusing element selects a final refresh rate signal. The selection of the final refresh rate signal occurs after the random access memory device is assembled into a chip package.

### BACKGROUND

This invention relates to a control circuit for use with a refresh request signal in a memory device. This circuit allows controllable adjustment to the rate of the refresh request signal.

In dynamic random access memories (DRAM), it is necessary for the information stored in the memory cells to be refreshed at cyclical intervals. Since, in DRAM memory cells, the information is stored as capacitor charges and the capacitors effect self-charging due to leakage currents, the stored charges on the capacitors have to be repeatedly renewed.

In many present day DRAM applications, the total amount of power consumed by the application, including by the DRAM, is becoming a major consideration. This is particularly important in the market driven by mobile applications. A major portion of the power that is consumed by the application's DRAM is during refresh operations. The DRAM's refresh operations are required to maintain the stored information in the memory cell that will otherwise be lost without refreshing. Thus, it is important that as little power as possible is consumed during the DRAM's retention mode, such as during self-refresh or auto-refresh.

A major factor determining the amount of power consumed by this refresh operation is the frequency of (how often) the refresh operation must take place. In present day DRAM applications, the refresh rate is typically set during the fabrication stage. Typically, during the production process of fabricating DRAMs, a certain amount of memory degradation can be expected within the DRAM. This memory degradation can be caused by adverse temperatures during the fabrication process, from various testing that is performed during fabrication, as well as other fabrication process considerations.

In practice, fabricators must forecast the amount of degradation expected in the DRAM. Once they have predicted the amount of memory retention fabricated DRAM is expected to have, they then set the refresh rate according to their projected forecast. This selection is made by laser fusing directly on the wafer before the packaging of the DRAM. Once the DRAM is packaged, since the entire DRAM is protected by plastic at that point, fusing elements are no longer available for laser fusing and the settings cannot be changed. It would be a useful improvement to allow a more custom setting of the refresh rate based on the actual performance of the DRAM after packaging has occurred, rather than on a forecasted estimate.

### SUMMARY

The present invention is a random access memory device assembled into a chip package with a refresh request control circuit, and a method for using the same. The refresh request control circuit includes a first circuit configured to receive a first refresh rate signal with a first refresh rate signal frequency. The first circuit produces a second refresh rate signal with a second refresh rate signal frequency. The refresh request control circuit also includes a second circuit configured to receive the first refresh rate signal and the second refresh rate signal. The refresh request control circuit also includes a final fusing element coupled to the second circuit. The final fusing element selects a final refresh rate signal. The selection of the final refresh rate signal occurs after the random access memory device is assembled into a chip package.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a prior art refresh rate control circuit.

FIG. 2 illustrates a refresh rate control circuit in accordance with the present invention.

FIG. 3 illustrates an exemplary flow diagram of a test method in accordance with the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

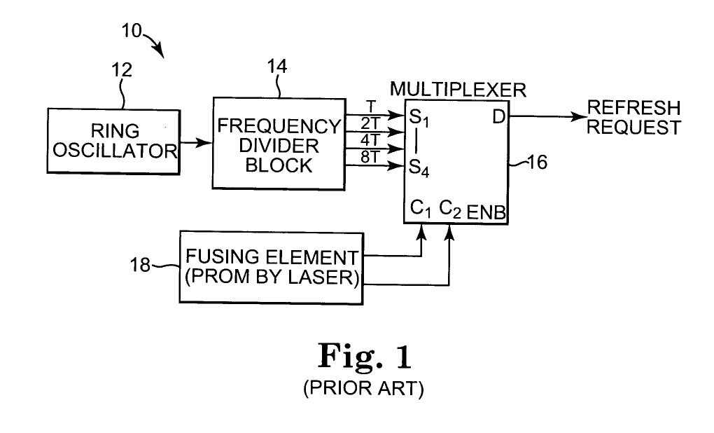

FIG. 1 illustrates prior refresh rate control circuit 10. Refresh rate control circuit 10 includes ring oscillator 12, frequency divider 14, multiplexer 16, and fusing element 18. Refresh rate control circuit 10 is a simplified block diagram of a circuit that generates a refresh request signal at a particular frequency in accordance with the prior art. Refresh rate control circuit 10 is used within a DRAM system where periodic refreshing of the memory is required to retain information in the memory. Refresh rate control circuit 10 generates a refresh signal at a particular rate that will control the refreshing of the DRAM.

Ring oscillator 12 is a signal generator that generates an oscillating initial signal having a particular period and frequency. Ring oscillator 12 delivers the initial signal to frequency divider 14. Frequency divider 14 then produces multiple output signals of varying frequency. The signal frequency of the multiple output signals produced by frequency divider 14 will vary from lower frequency to higher frequency in multiples of each other. For example, frequency divider 14 may produce a high frequency signal with a period of T and decreasingly lower frequency signals with periods of 2T, 4T, and 8T. A signal with a period of 8T will be the slowest signal produced by frequency divider 14, as its period is 8 times as long as the period of signal T.

The various signals from frequency divider 14 are fed to multiplexer 16, which is illustrated as a four-input multiplexer, with inputs S₁-S₄, and controlled by two-input gates, C₁ and C₂. Fusing element 18 provides input to the two-input gates C₁ and C₂ of multiplexer 16. Fuse element 18 is typically blown by a laser during the fabrication process while the memory device is still at the wafer level. By leaving uncut or by cutting one or all of the fuses of fusing element 18, it is possible to programmably select the appropriate refresh rate from among the four signals T, 2T, 4T and 8T provided to multiplexer 16 by frequency divider 14.

This programming or selecting is done at the front end of the production while the memory is still at the wafer level. Typically, this programming is done before the memory has gone through production and reliability testing that can affect the retention characteristics of the memory device. Consequently, the degradation of the memory device must be forecasted and programming of the refresh rate is determined in accordance with that forecast. Reliability tests such as burn-in can degrade the retention characteristics of the memory device by affecting only a few or, in some cases, most of the memory cells.

For the sake of good product margin, a refresh rate is typically programmed at a conservative rate to ensure sufficient refresh operation is taking place. In other words, the frequency of the refresh signal will be higher than needed to retain memory in the device. Once refresh rate control circuit 10 is assembled into a DRAM package form, it can no longer be reprogrammed to change the refresh rate that was initially selected. Fusing elements may no longer be accessed since all aspects of the DRAM are protected by plastic. So if it is determined that the selected refresh rate is faster than needed to retain information in the assembled DRAM chip package after the package is assembled, there is no way to decrease the rate to lower the power consumption of that DRAM chip package. Similarly, if it determined that the selected refresh rate is slower than needed to retain information in the assembled DRAM chip package after the package is assembled, there is no way to increase the rate and the chip must be discarded since it will not properly retain information in memory. This is why a conservative refresh rate is selected.

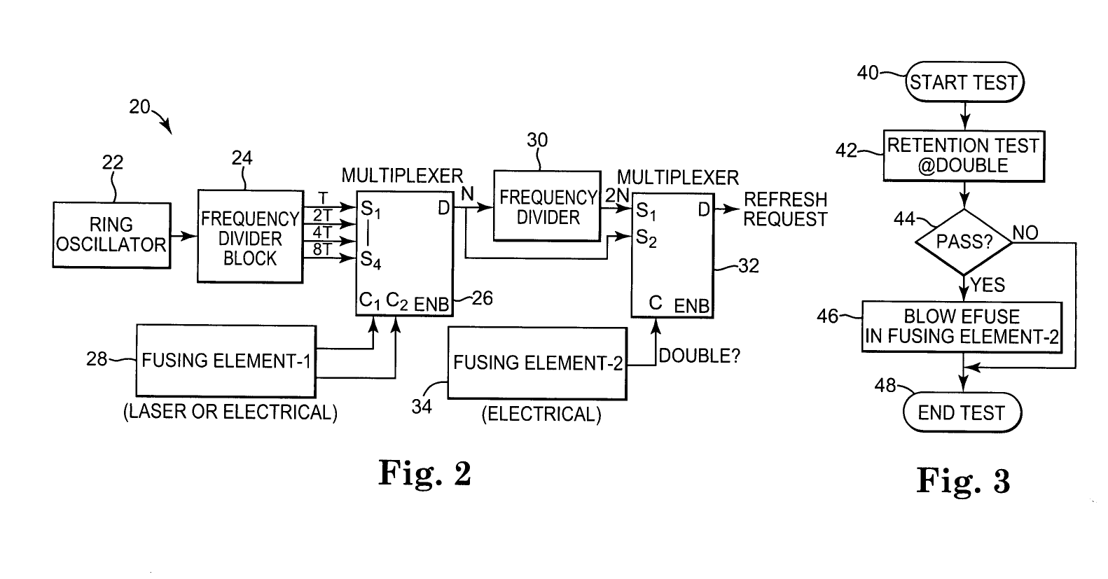

FIG. 2 illustrates an exemplary implementation of the refresh rate control circuit 20 in accordance with the present invention. Refresh rate control circuit 20 includes ring oscillator 22, first frequency divider 24, first multiplexer 26, first fusing element 28, second frequency divider 30, second multiplexer 32, and second fusing element 34. Refresh rate control circuit 20 is used within a DRAM system where periodic refreshing of the memory is required to retain information in the system memory. Refresh rate control circuit 20 generates a refresh signal at a particular rate that will control the refreshing of the DRAM. With refresh rate control circuit 20, adjustments can be made to the refresh rate at the back end of the fabrication process.

Ring oscillator 22 is a signal generator that produces an oscillating initial signal with a particular period and frequency. The initial signal from ring oscillator 22 is provided to first frequency divider 24. First frequency divider 24 then provides multiple output signals of varying frequency, which are derived from the input signal from ring oscillator 22. The signal frequency of the multiple output signals produced by first frequency divider 24 will vary from lower frequency to higher frequency in multiples of each other. For example, first frequency divider 24 may produce a high frequency signal with a period of T and decreasingly lower frequency signals with periods of 2T, 4T, and 8T. A signal with a period of 8T will be the slowest signal produced by first frequency divider 24, as its period is 8 times as long as the period of signal T.

These signals from first frequency divider 24 are provided to first multiplexer 26, shown in FIG. 2 as a four-input multiplexer with inputs S₁-S₄, and controlled by two-input gates, C₁ and C₂. One of those signals may then be selected for output from the multiplexer by controlling the input states with first fusing element 28. First fusing element 28 provides input signals to the two input gates C₁ and C₂ of first multiplexer 26.

First fusing element 28 is typically blown by a laser during the fabrication process while the memory device is still at the wafer level. With the present invention, first fusing element 28 is also programmable electrically so that the adjustment of refresh rate can be taken place after the DRAM is in package form as well. By leaving uncut or by cutting one or all of the fuses of first fusing element 28, it is possible to programmably select the output signal from among the four signals T, 2T, 4T and 8T provided to first multiplexer 26 by first frequency divider 24. Typically, programming of first fusing element 28 is done at the front end of production while the memory is still at the wafer level and before the retention characteristics of the memory device have been established.

First fusing element 28 is programmably controlled to select one of the multiple rates provided to first multiplexer 26 to be used as the output signal N from first multiplexer 26. This output signal N from first multiplexer 26 is provided to second frequency divider 30 and to input S₁ of second multiplexer 32. Second frequency divider 32 then further divides the frequency of output signal N received from first multiplexer 26 and generates an input signal 2N for input S₂ of second multiplexer 32. Consequently, second multiplexer 32 receives a signal N from first multiplexer 26 at input S₂ and a signal 2N from second frequency divider 30 at input S₁. Signal 2N from second frequency divider 30 is half the frequency and has twice the period of signal N received from first multiplexer 26. In this way, signal 2N is derivative of signal N.

The selection between the two signals N and 2N received by a second multiplexer 32 at inputs S₁ and S₂ is controlled by second fusing element 34. Second fusing element 34 is an electrical fuse, which is blown by electrical stress such as excessive voltage. By cutting second fusing element 34, second multiplexer 32 is controlled to select between two frequency signals N and 2N at the back end of the fabrication process. The selected signal is the refresh request signal used to refresh the DRAM.

With refresh rate control circuit 20 of the present invention, adjustments can be made to the rate of the refresh request signal of the DRAM in accordance with the actual retention characteristics of the memory device, rather than just an estimation of the retention characteristics. Once the DRAM is in a package form, first fusing element 28 is often not longer accessible and can no longer be manipulated to adjust the rate of the refresh request signal. This is especially true when first fusing element 28 is a laser fusing element. Fusing element 34, however, is accessible and provides extra flexibility such that refresh rate control circuit 20 can be adjusted to affect the refresh rate. Similarly, when first fusing element 28 is electrically programmable, it can also be programmed after packaging of the DRAM providing system flexibility. After all tests that can affect retention characteristics of the memory have been completed, second fusing element 34 can be cut or not cut in order to adjust the rate of the refresh request signal in accordance with the actual retention characteristics of the memory device.

FIG. 3 illustrates a process by which refresh rate control circuit 20 is tested and programmed for use within a system using DRAM. Initially, refresh rate control circuit 20 is programmed such that first fusing element 28 is set to select a signal at first multiplexer 26 based on forecasting done in the fabrication process. The first fusing element 28 is cut electrically or by laser at the wafer level. This will select an initial rate and period for the refresh request signal. The DRAM is then fabricated into a package. After this initial setting is made and the DRAM is packaged, the testing process illustrated in FIG. 3 is initiated at block 40.

The first step of the process is to determine the actual retention characteristics of the subject DRAM. At block 42 the DRAM retention is tested at a signal period that is double the period (half the rate) of the initial refresh request signal to verify whether data is retained in memory. A decision is then made at block 44 to determine whether or not memory retention was sufficient at this double refresh rate period. If memory test was not successful, that is, data was not sufficiently retained in memory, control is passed to block 48 where the test is ended. In this way, the initial rate selected for the refresh request signal is retained.

If the test passed at block 44 and memory retention was verified, control is passed to block 46 where second fusing element 34 will be blown in order to increase the refresh period. Since the retention test at block 42 verified that subject DRAM could retain data at a slower refresh request signal rate, the slower rate is selected, thereby saving power in the memory system during the refresh cycle.

The example illustrated by FIG. 3 shows an increase of the period of the refresh request signal. However, it will be clearly understood by one skilled in the art that it is similarly possible to decrease the period of refresh request signal though a highly similar test. In other words, by choosing a longer period for the refresh request signal period initially, it is then possible to chop down the period of the refresh rate by fuse programming after testing verifies that data is not being retained at the initially-selected longer period.

Similarly, it is also possible to introduce additional options for the period of the refresh rate signal by adding additional outputs to second frequency divider 30 and additional inputs to second multiplexer 32, and by adding additional elements to second fusing element 34. With the improved refresh rate control circuit 20 these adjustments to the period of the refresh rate signal can be made after the DRAM has been packaged by taking advantage of the electrical fuse characteristics of second fusing element 36. Unlike previous laser fusing elements that must be modified at the wafer level, the fusing element of the present invention may be modified after packaging, and therefore, can be more closely tailored to the actual retention characteristics of the DRAM product.

Although specific embodiments have been illustrated and described herein, it will be appreciated by those of ordinary skill in the art that a variety of alternate and/or equivalent implementations may be substituted for the specific embodiments shown and described without departing from the scope of the present invention. For example, the number of rates for the refresh signal that are available for selection may be varied depending on the needs of any particular situation. Similarly, the specific process for testing the retention characteristics of the memory and then adjusting the rate is not restricted to the examples shown, and may vary in order to ensure that the appropriate rate is selected for the refresh signal that will retain data in the memory. This application is intended to cover any adaptations or variations of the specific embodiments discussed herein. Therefore, it is intended that this invention be limited only by the claims and the equivalents thereof.

1. A random access memory device assembled into a chip package and including a refresh request control circuit, the refresh request control circuit comprising:
a first circuit configured to receive a first refresh rate signal having a first refresh rate signal frequency and configured to produce a second refresh rate signal having a second refresh rate signal frequency;
a second circuit configured to receive the first refresh rate signal and the second refresh rate signal; and
a final fusing element coupled to the second circuit such that the final fusing element selects a final refresh rate signal, the selection of the final refresh rate signal occurring after the dynamic memory storage system has been assembled into a chip package.

2. The random access memory device of claim 1 including a multitude of memory cells that must be periodically refreshed in order to retain data, the final refresh rate signal having a final refresh rate signal frequency that is sufficient to refresh the memory cells often enough to retain data.

3. The random access memory device of claim 2 wherein the final refresh rate signal is selected from the first and second refresh rate signals.

4. The random access memory device of claim 3 wherein second refresh rate that is different than, and a derivative of, the first refresh rate frequency

5. The random access memory device of claim 1 further comprising:
a third circuit configured to produce multiple interim signals of varying frequencies;
a fourth circuit configured to receive the multiple interim signals of varying frequencies; and
an initial fusing element coupled to the fourth circuit such that the initial fusing element selects the first refresh rate signal from the multiple interim signals of varying frequencies.

6. The random access memory device of claim 5 wherein the initial fusing element selects the first refresh rate signal by laser cutting a fuse in the initial fusing element while the random access memory device is at a wafer level of processing.

7. The random access memory device of claim 5 wherein the initial fusing element selects the first refresh rate signal by electronically cutting a fuse in the initial fusing element.

8. The random access memory device of claim 5 wherein third circuit is a frequency divider and the fourth circuit is a multiplexer.

9. The random access memory device of claim 1 wherein the final fusing element selects the final refresh rate signal by electronically cutting a fuse in the final fusing element after random access memory device is assembled into a chip package.

10. A refresh request control circuit for use in a random access memory device assembled into a chip package and having a multitude of memory cells that must be periodically refreshed in order to retain data, the refresh request control circuit comprising:
a signal generator that produces an oscillating signal;
a first frequency divider configured to receive the oscillating signal from the first frequency divider and to produce multiple output signals, each having a different frequency;
a first multiplexer configured to receive the multiple output signals from the first frequency divider;
a first fusing element coupled to the first multiplexer such that the first fusing element selects a first refresh rate signal from the multiple output signals, the first refresh rate signal having a first refresh rate signal frequency;
a second frequency divider configured to receive the first refresh rate signal from the first multiplexer and to produce a second refresh rate signal having a second refresh rate signal frequency that is different than the first refresh rate signal frequency;
a second multiplexer configured to receive the first and second refresh rate signals; and
a second fusing element coupled to the second multiplexer such that the second fusing element selects a final refresh rate signal, the selection occurring after the random access memory device has been assembled into a chip package.

11. The random access memory device of claim 10 wherein the final refresh rate signal has a signal frequency that is sufficient to refresh the memory cells often enough to retain data in the random access memory device.

12. The random access memory device of claim 10 wherein the first fusing element selects the first refresh rate signal by laser cutting the first fusing element while the random access memory device is at a wafer level.

13. A method of setting the refresh signal rate for periodically refreshing memory cells in a random access memory device that is assembled into a chip package, the method including the steps of:
providing a random access memory device with a multitude of memory cells and a refresh rate control circuit;
initially programming the refresh rate control circuit such that it generates a first refresh rate signal with an first refresh rate signal frequency;
determining whether the first refresh rate signal frequency is sufficient to retain data in the memory cells of the random access memory device;
providing a second refresh rate signal having a second refresh rate signal frequency; and
after the random access memory device is assembled into a chip package, further programming the refresh rate control circuit to select a final refresh rate signal based on the determination of whether the first refresh rate signal frequency is sufficient to retain data in the memory cells.

14. The method of claim 13 further including receiving the first and second refresh rate signals with a multiplexer that can be controlled to select the final refresh rate signal for output from the multiplexer to be used in refreshing the memory cells of the random access memory device.

15. The method of claim 14 wherein the step of further programming the refresh rate control circuit to provide the final refresh rate signal includes cutting or leaving uncut a fusing element, which is coupled to the multiplexer such that the fusing element controls the multiplexer and the selection of the final refresh rate signal.

16. The method of claim 13 wherein the step of determining whether the first refresh rate signal frequency is sufficient to retain data in the memory cells of the random access memory device occurs after the random access memory device is packaged into a chip.

17. A random access memory device assembled into a chip package and including a refresh request control circuit, the refresh request control circuit comprising:
first means for receiving a first refresh rate signal having a first refresh rate signal frequency and for producing a second refresh rate signal having a second refresh rate signal frequency; and
second means for receiving the first refresh rate signal and the second refresh rate signal and for selecting a final refresh rate signal after the random access memory device has been assembled into a chip package.

18. The random access memory device of claim 17 wherein first means includes a frequency divider.

19. The random access memory device of claim 17 wherein second means includes a multiplexer and a fusing element, the multiplexer configured to receive the first and second refresh rate signals.

20. The random access memory device of claim 18 wherein the fusing element controls the multiplexer in order to select the final refresh rate signal after the random access memory device has been assembled into a chip package.
